(19) United States
(12) Patent Application Publication
(10) Pub. No.: US 2008/0210300 A1
(43) Pub. Date: Sep. 4, 2008

(54) Method of Producing Substrate for Thin Film Photoelectric Conversion Device, and Thin Film Photoelectric Conversion Device

(76) Inventors: Tomomi Meguro, Shiga (JP); Kenji Yamamoto, Hyogo (JP)

Correspondence Address: BIRCH STEWART KOLASCH & BIRCH, PO BOX 747, FALLS CHURCH, VA, 22040-0747, US

(21) Appl. No.: 11/886,243

(22) PCT Filed: Mar. 7, 2006
(86) PCT No.: PCT/JP2006/304306

§ 371 Date: Sep. 13, 2007

(30) Foreign Application Priority Data
Mar. 15, 2005 (JP) 2005-072234

(51) Int. Cl. H01L 31/00

(52) U.S. Cl. 136/256

(57) ABSTRACT

This invention provides a method of producing a substrate for a thin film photoelectric conversion device, the substrate being able to make it possible to fabricate the thin film photoelectric conversion device free from lowering in its open-circuit voltage or its fill factor even when the substrate includes a transparent conductive film that is mainly composed of zinc oxide and has a relatively large haze ratio for causing a large optical confinement effect. The method of producing the substrate for the thin film photoelectric conversion device according to the present invention is characterized in that a transparent conductive film formed on a transparent insulator base, which is mainly composed of zinc oxide and having a haze ratio of at least 5%, is etched with an acid or alkali solution. Output properties of the thin film photoelectric conversion device fabricated using the substrate is improved because the etching with acid or alkali can remove steep protrusions, which cause decrease in Voc or FF, in a textured structure on a surface of the film.

### TECHNICAL FIELD

The present invention relates to a method of producing a substrate having high transmittance, low electric resistance and an excellent surface shape to be used for a thin film photoelectric conversion device, and relates to a thin film photoelectric conversion device fabricated with the substrate.

### BACKGROUND ART

In recent years, importance of a transparent conductive film has increasingly been rising. The transparent conductive film is used as a material for a transparent electrode in each of various light receiving devices such as a thin film photoelectric conversion device typified by a solar cell or of display devices of liquid crystal, PDP, EL, and the like. In particular, the transparent conductive film for a thin film photoelectric conversion device should have high transparency, high electric conductivity, and surface unevenness for effective use of light. As the transparent conductive film, there are now known films of indium oxide (In₂O₃) to which a small amount of tin has been added (hereinafter denoted as doped, and a substance added with a small amount is denoted as a dopant), tin oxide (SnO₂) doped with antimony or fluorine for better conductivity, zinc oxide (ZnO), and the like.

Since the indium oxide film (hereinafter referred to as ITO) has high conductivity, it is widely used. On the other hand, the source material of In is a rare metal and the industrial production amount thereof is small. Therefore, if demand for the transparent conductive film increases, stable supply of the film will come into question. In addition, since In is expensive, cost reduction of the film is also limited.

SnO₂ is inexpensive compared to ITO, and then it has a low density of free electrons and makes it possible to form a film of high transmittance. However, SnO₂ is disadvantageously low in conductivity and in resistance to plasma.

In contrast, zinc is much included in the natural resources and thus is inexpensive. In addition, a zinc oxide film has high resistance to plasma and has high electron mobility that enhances transmittance of light having a longer wavelength. Therefore, the zinc oxide film is suitable for the transparent conductive film to be used for the thin film photoelectric conversion device, and the transparent conductive film mainly composed of zinc oxide as a material alternative to ITO or SnO₂ is now under development.

A sputtering method is an exemplary method of forming a zinc oxide film. When a zinc oxide film is formed by a sputtering method, however, fine unevenness (hereinafter referred to as texture) on a surface of the film is less likely formed and then optical confinement effect due to scattering of light in a thin film photoelectric conversion device including that film is lowered leading to decrease of electric power generation. Therefore, when the zinc oxide film is formed by the sputtering method, it has been necessary to form surface unevenness by immersing and etching the film in an acid or alkali solution. For example, according to the disclosure in Patent Document 1, a zinc oxide film formed by a sputtering method and not having a textured structure is etched with acid or alkali to have a textured structure, and then the short-circuit current density (Jsc) of a thin film photoelectric conversion device including the etched zinc oxide film is improved as a result of the optical confinement effect due to the textured structure.

### Patent Document 1: Japanese Patent Laying-Open No. 1′-233800

### DISCLOSURE OF THE INVENTION

### Problems to be Solved by the Invention

It has been difficult to control the textured structure on the zinc oxide film having surface unevenness formed by such etching as disclosed in Patent Document 1. That is, depending on the etching condition, the surface unevenness becomes steep and then coverage of an Si layer which is a semiconductor layer of a thin film photoelectric conversion device and formed on the zinc oxide film becomes insufficient, which results in decrease in the open-circuit voltage (Voc) and particularly in the fill factor (FF) of the formed thin film photoelectric conversion device, as compared with an example without performing etching.

### Means for Solving the Problems

A method of producing the substrate for the thin film photoelectric conversion device according to the present invention is characterized in that a transparent conductive film formed on a transparent insulator base, which is mainly composed of zinc oxide and having a haze ratio of at least 5%, is etched with an acid or alkali solution. Output properties of the thin film photoelectric conversion device fabricated using the substrate is improved because the etching with acid or alkali can remove steep protrusions, which cause decrease in Voc or FF, in a textured structure on a surface of the film.

Preferably, the transparent conductive film is formed by a CVD method. This is because the textured structure varies depending on a film deposition condition and thus the optical confinement effect due to scattering of light can be controlled. Particularly preferably, the transparent conductive film before etching has a haze ratio in a range from at least 10% to at most 40%. This is because a higher haze ratio is preferred in terms of the optical confinement effect, while a higher haze ratio results from a higher ratio of increased surface unevenness and hence causes significant decrease in the open-circuit voltage (Voc).

In addition, preferably, the etching causes a change rate of at most ±20% in the haze ratio and a decrease rate of 10% to 26% in SDR (surface area ratio). This is because the etching can remove fine protrusions on the film surface while forming the texture effective for optical confinement. In addition, preferably, the etching is performed by immersing the transparent conductive film on the transparent insulator base into 0.05 to 2 vol % acetic acid solution for 1 to 20 seconds. This is because the etching can remove fine protrusions on the film surface while forming the texture effective for optical confinement.

An acid solution to be used in the etching is preferably a liquid composed of one or more selected from the group consisting of acetic acid, hydrochloric acid, nitric acid, and hydro-fluoric acid.

An alkali solution to be used in the etching is preferably a liquid composed of one or more selected from the group consisting of sodium hydroxide, ammonia, potassium hydroxide, and calcium hydroxide.

A thin film photoelectric conversion device having a large short-circuit current density (Jsc) due to the optical confinement effect, improved open-circuit voltage (Voc), and fill factor (FF) can be provided by successively stacking a photoelectric conversion unit and a back electrode layer on the substrate produced by the method of the present invention as described above.

### EFFECTS OF THE INVENTION

According to the method of producing the substrate for the thin film photoelectric conversion device of the present invention, output properties of the thin film photoelectric conversion device fabricated using the substrate is improved because the etching with acid or alkali can remove steep protrusions, which cause decrease in Voc or FF, in a textured structure on a surface of the transparent conductive film mainly composed of zinc oxide and having a relatively large haze ratio causing a large optical confinement effect.

### BRIEF DESCRIPTION OF THE DRAWINGS

FIG. 1 is a schematic cross-sectional view showing a layered structure of a substrate for a thin film photoelectric conversion device according to the present invention.

FIG. 2 is a schematic diagram and an expression showing definition of SDR.

FIG. 3 is a schematic cross-sectional view showing a layered structure of a thin film photoelectric conversion device of the present invention.

### DESCRIPTION OF THE REFERENCE SIGNS

10 transparent insulator base
11 transparent ground base
12 insulating underlayer
13 transparent conductive film
20 amorphous silicon photoelectric conversion unit
21 p-type microcrystalline layer
22 p-type amorphous silicon carbide layer
23 i-type amorphous silicon layer
30 back electrode layer
31 zinc oxide layer
32 Ag layer

### BEST MODES FOR CARRYING OUT THE INVENTION

As described previously with reference to Patent Document 1, although it is preferable to increase the surface unevenness in order to enhance the optical confinement effect, it is pointed out that such increase of the surface unevenness may cause sharper level variation and then may cause deterioration in properties of the thin film photoelectric conversion device. With the sharper level variation, there occurs decrease in the open-circuit voltage (Voc) and fill factor (FF), and hence decrease in the conversion efficiency (Eff), as to the properties of the thin film photoelectric conversion device. In some cases, the short-circuit current density (Jsc) is also decreased.

The reason for the deterioration in properties of the thin film photoelectric conversion device is considered as follows. If the level variation becomes sharper and then acute-angular protrusions and gorge-like recesses are formed on the transparent electrode layer, growth of the thin film semiconductor layer is hindered thereby, so that the transparent electrode layer cannot uniformly be covered with the semiconductor layer and then so-called “poor-coverage” occurs. As a result, there occurs increase in the contact resistance and leakage current, which causes decrease mainly in Voc and FF, and hence decrease in Eff. Furthermore, the sharper level variation hinders growth of the semiconductor layer over the transparent electrode layer, deteriorates film quality of the semiconductor layer, and causes more loss owing to carrier recombination, which then causes decrease in Voc, FF and Jsc, and hence decrease in Eff.

In view of the above-described problems and the problem of the sharper level variation, the present inventors assumed that output properties of the thin film photoelectric conversion device may be improved, for example, by forming in advance a transparent electrode film mainly composed of zinc oxide and having a relatively large haze ratio by a CVD method and etching away steep protrusions, which cause decrease in Voc or FF, in the textured structure of the surface with acid or alkali, contrary to the method of forming surface unevenness by etching the flat transparent conductive film as disclosed in Patent Document 1. Then, the present inventors conducted studies as follows and finally completed the present invention.

A preferable embodiment of the present invention will hereinafter be described with reference to the drawings. In the drawings of the present application, dimensions such as thickness and length are modified as appropriate for clarity and simplification of the drawings, so that actual dimensional relations are not shown. In the drawings, the same reference character represents the same or corresponding portion.

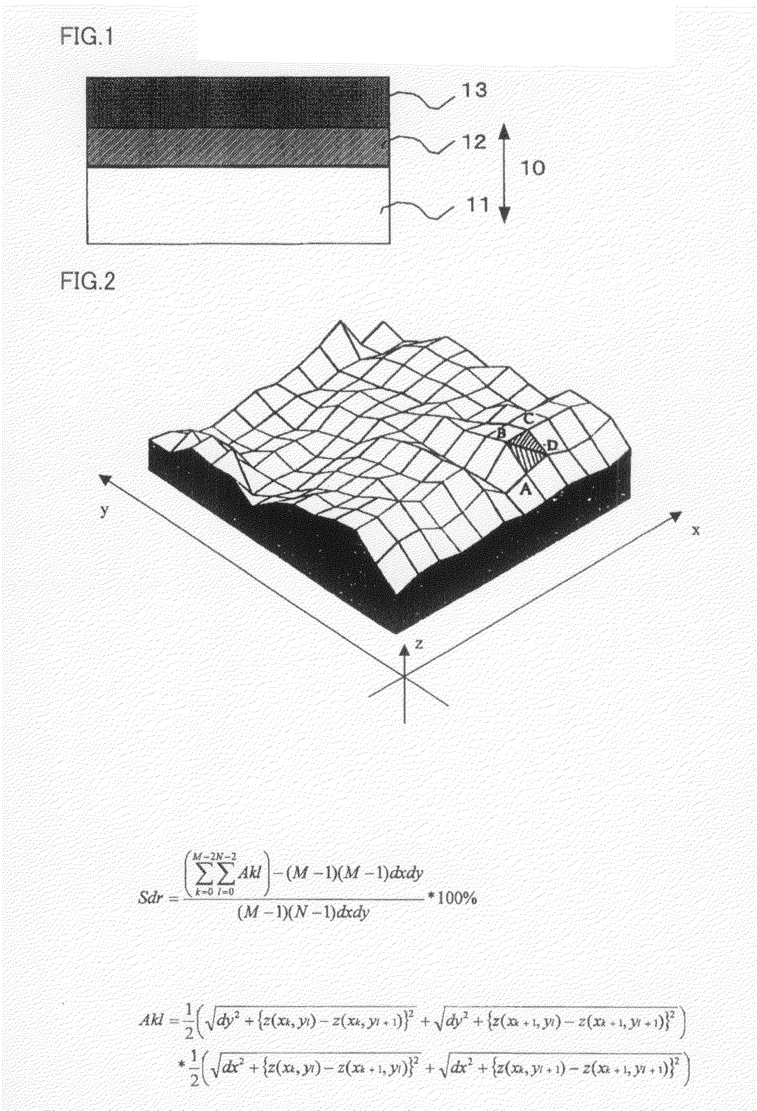

Initially, a method of forming a substrate for a thin film photoelectric conversion device in one embodiment of the present invention will be described with reference to FIG. 1.

FIG. 1 shows an exemplary substrate for a thin film photoelectric conversion device, which is produced by the method according to the present invention. A transparent insulator base 10 is constituted of a transparent ground base 11 and an insulating underlayer 12, and a transparent conductive film 13 mainly composed of zinc oxide is further formed on insulating underlayer 12.

A glass plate, a transparent resin film or the like may be used for transparent ground base 11. As the glass plate, it is possible to use a soda lime glass plate having opposite smooth main surfaces and mainly composed of SiO₂, Na₂O and CaO, which can be obtained with its large area at a low cost and has high transparency and insulation effect.

Insulating underlayer 12 preferably contains fine particles composed at least of silicon oxide (SiO₂), because SiO₂ has a lower refraction index compared to the transparent conductive layer, which is close to that of transparent ground base 11 such as of glass. In addition, since SiO₂ has high transparency, it is suitable for a material used on a light incident side. Moreover, in order to adjust the refraction index of insulating underlayer 12, it is possible to include fine particles of titanium oxide (TiO₂), aluminum oxide (Al₂O₃), indium tin oxide (ITO), zirconium oxide (ZrO₂), magnesium fluoride (MgF₂), or the like in addition to SiO₂. When soda lime glass is used for transparent ground base 11, insulating underlayer 12 can be utilized as an alkali barrier film for preventing an alkali component in the glass from entering transparent conductive film 13, and also utilized to obtain an effect to improve adhesion between transparent conductive film 13 and transparent ground base 11. Further, in order to control the texture shape of transparent conductive film 13, insulating underlayer 12 itself may have a fine textured structure.

While various methods may be used for the method of forming insulating underlayer 12 on the surface of transparent ground base 11, it is preferable to use a roll coat method of applying fine particles along with a binder-forming material containing a solvent, because the fine particles contribute to uniformly form a closely packed underlayer.

A transparent conductive film mainly composed of zinc oxide is used as a material for transparent conductive film 13 arranged on the transparent insulator base, because the textured structure having a large haze ratio is readily formed, for example, by using a CVD method.

While a sputtering method, an evaporation method, an electron beam evaporation method, an electrodeposition method, a CVD method, and the like may be used for the method of forming the transparent conductive film mainly composed of zinc oxide, a CVD method is preferable for the above-described reasons. In this case, the CVD method refers to formation of zinc oxide through chemical reaction in vapor phase, for example, at a deposition temperature of 150° C. or higher, at a pressure of 5 to 1000 Pa, and by using organic zinc as a source gas, an oxidizer, a doping gas, and a dilution gas. While diethyl zinc (DEZ) or dimethyl zinc may be used as organic zinc, DEZ is preferred because of its easy availability and its good reactivity with the oxidizer. While as the oxidizer, it is possible to use water, oxygen, carbon dioxide, carbon monoxide, dinitrogen oxide, nitrogen dioxide, sulfur dioxide, dinitrogen pentoxide, alcohols (R(OH)), ketones (R(CO)R′), ethers (ROR′), aldehydes (R(COH)), amides ((RCO)ₓ(NH₃₋ₓ), x=1, 2, 3), and sulfoxides (R(SO)R′) (R and R′ represent alkyl group), water is preferred because of its easiness in handling and its good reactivity with organic zinc. While rare gases (He, Ar, Xe, Kr, Rn), nitrogen, hydrogen, and the like may be used as the dilution gas, hydrogen is preferably used because it has high heat conductivity and is excellent in causing thermal uniformity of the substrate. While diborane (B₂H₆), alkyl aluminum, alkyl gallium, and the like may be used as the doping gas, it is preferable to use diborane excellent in its decomposition efficiency. Since water is in a liquid state at a room temperature and an atmospheric pressure, water is to be supplied after it is vaporized by heating, bubbling, spraying, or the like. Here, the thin film preferably has a grain size of approximately 50-500 nm and surface unevenness with level variation of approximately 20-200 nm in view of the optical confinement effect of a thin film crystalline solar cell. The deposition temperature herein refers to a temperature of a surface of the base kept in contact with a heating unit of a film-forming device.

Transparent conductive film 13 is mainly composed of zinc oxide. This transparent conductive film has an average thickness preferably in a range from 0.5 to 5 μm and more preferably in a range from 1 to 3 μm. This is because excessively small thickness hardly provides sufficient surface unevenness that effectively contributes to the optical confinement effect and also makes it difficult to obtain electrical conductivity required to serve as a transparent electrode, while an excessively large thickness causes light absorption by the zinc oxide film itself, whereby reducing the quantity of light reaching to the photoelectric conversion unit through the zinc oxide and thus causing decrease in efficiency. Furthermore, the excessively thick film requires longer time for film formation, which increases film formation costs.

Then, transparent conductive film 13 is etched with an acid or alkali solution so as to remove the steep protrusions on its surface. Here, the etching liquid to be used may be acidic or alkaline, because zinc oxide is an amphoteric compound that reacts with both of an acidic solution and an alkaline solution. While for the acidic solution, it is possible to use acetic acid, hydrochloric acid, nitric acid, hydro-fluoric acid, and the like, acetic acid and hydrochloric acid are preferred because of their easiness in handling and their inexpensiveness. The acidic liquid may be a liquid composed of one type, or a mixed liquid of two or more types. While for the alkaline solution, it is possible to use sodium hydroxide, ammonia, potassium hydroxide, calcium hydroxide, and the like, sodium hydroxide is preferred because of its easiness in handling and its inexpensiveness. The alkaline liquid may be a liquid composed of one type, or a mixed liquid of two or more types. As to the etching method, the transparent conductive film may be immersed in an etchant, or the etchant may be sprayed over the surface of the transparent conductive film. In order to remove the residual etchant on the surface of the transparent conductive film, the film may be immersed in pure water or the pure water may be sprayed over the film.

Successively, by drying in an oven of which temperature is adjusted to 100° C. or higher, the substrate for the thin film photoelectric conversion device is completed. The oven may be filled with a gas not changing properties of zinc oxide, and the gas may be air, nitrogen, rare gas such as argon or helium, and the like.

A thickness, a haze ratio, and an SDR (surface area ratio) of the formed zinc oxide (ZnO) film serving as the transparent conductive film were measured with an ellipsometer, a haze meter, and an AFM (atomic force microscope), respectively. The haze ratio refers to a value obtained by calculating (diffusion transmittance/total transmittance)×100, and it was measured with a method complying with JIS K7136. The SDR refers to a ratio of a surface area of surface unevenness with respect to the flat surface, as defined in the drawing and the expression in FIG. 2, and it can be said that a greater ratio indicates presence of a greater number of finer surface unevenness.

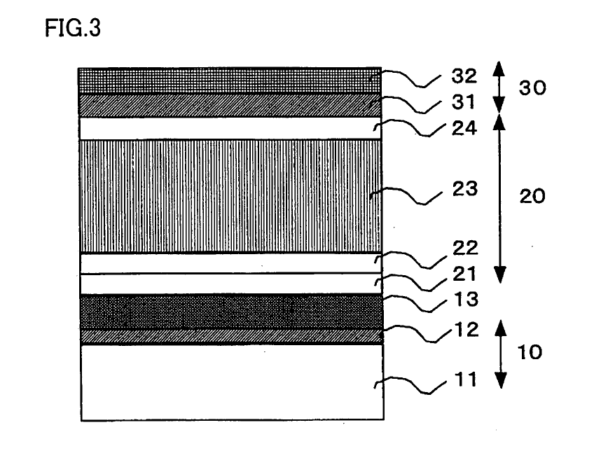

A thin film photoelectric conversion device in one embodiment of the present invention is now described with reference to FIG. 3.

FIG. 3 shows an exemplary thin film photoelectric conversion device fabricated utilizing the method of producing the substrate for the thin film photoelectric conversion device according to the present invention, representing a silicon-based thin film solar cell including an amorphous silicon photoelectric conversion unit.

Initially, an amorphous silicon photoelectric conversion unit 20 is formed by a plasma CVD method on transparent conductive film 13 of the substrate obtained by the method of producing the substrate according to the present invention as described previously. Amorphous silicon photoelectric conversion unit 20 has sensitivity to light of approximately 360 to 800 nm wavelength. Amorphous silicon photoelectric conversion unit 20 includes a p-type microcrystalline layer 21, a p-type amorphous silicon carbide layer 22, an i-type amorphous silicon layer 23, and an n-type layer 24.

P-type microcrystalline layer 21 is formed introducing silane, diborane and hydrogen in the CVD chamber, and its thickness is set in a range from 5 nm to 30 nm. The reason why such a microcrystalline layer is formed on the zinc oxide layer is that ohmic characteristic between p-type amorphous silicon carbide layer 22 and zinc oxide is poor, which causes decrease in FF. Therefore, in order to further improve the ohmic characteristic, an additional microcrystalline layer formed by adding methane to silane, diborane and hydrogen may be interposed between the p-type microcrystalline layer and the zinc oxide layer. Furthermore, in order to clean the surface of the zinc oxide layer to improve the junction thereon, plasma treatment using hydrogen, argon, nitrogen, or the like may be performed.

Amorphous silicon carbide layer 22 is formed introducing silane, diborane, hydrogen, and methane into the chamber. Here, the film thickness is set in a range from 5 nm to 50 nm. Thereafter, i-type amorphous silicon layer 23 is formed to a thickness in a range from 100 nm to 500 nm by introducing silane and hydrogen as a film-forming gas. Further, n-type layer 24 is formed to a thickness in a range from 5 nm to 50 nm by introducing silane, phosphine and hydrogen into the chamber as a film-forming gas.

Thereafter, a back electrode layer 30 is formed on amorphous silicon photoelectric conversion unit 20. Back electrode layer 30 preferably has a two-layered structure constituted of a zinc oxide layer 31 and an Ag layer 32. While zinc oxide layer 31 may be formed by a sputtering method or a CVD method, it is preferably formed by a CVD method because electrical damage to the silicon layer can be mitigated. Ag layer 32 can be formed by a sputtering method or an evaporation method. In the present description, an amorphous photoelectric conversion unit is illustrated as a power generation layer of the thin film photoelectric conversion device, but a material for the power generation layer is not limited as such. The power generation layer may be implemented by a crystalline photoelectric conversion unit having absorption in a main wavelength region of sunlight (400 nm to 1200 nm), or by a layered structure including the amorphous and crystalline units.

Several examples will be described hereinafter as specific examples of the embodiment above, together with a comparative example.

### EXAMPLES

### Example 1

Initially, zinc oxide film 13 was formed as the transparent conductive film on transparent insulator base 10 that includes transparent ground base 11 of a glass plate and insulating underlayer 12 of SiO₂ formed thereon, and its SDR and haze ratio were measured.

Specifically, transparent insulator base 10 was initially loaded in a film-forming chamber, and then hydrogen and diborane were introduced at 1500 sccm and 500 sccm into the chamber respectively and the insulator base was held for 30 minutes at a deposition temperature of 150° C. Successively, the zinc oxide film was deposited to 1.5 μm thickness under conditions in which vaporized water and diethyl zinc were introduced at 900 sccm and 800 sccm respectively and the pressure in the film-forming chamber was held at 45 Pa. The film thickness was measured with an ellipsometer. The SDR was measured with the AFM and found as 67, while the haze ratio was measured with the haze meter and found as 18%.

Thereafter, the zinc oxide film was immersed in 1 vol % acetic acid aqueous solution held at 20° C. for 5 seconds, and then immersed in pure water for 180 seconds for rinsing. Thereafter, the substrate was dried in an atmosphere of air in an oven held at 200° C., and then the substrate for the thin film photoelectric conversion device was completed. The SDR and the haze ratio of the substrate for the thin film photoelectric conversion device were measured and found as 60 and 19%, respectively.

Further, amorphous silicon photoelectric conversion unit 20 was formed by a plasma CVD method and back electrode layer 30 was successively formed, thereby fabricating the thin film photoelectric conversion device.

Specifically, amorphous silicon photoelectric conversion unit 20 was initially formed on zinc oxide film 13 by a plasma CVD method. Amorphous silicon photoelectric conversion unit 20 includes p-type microcrystalline layer 21, p-type amorphous silicon carbide layer 22, i-type amorphous silicon layer 23, and n-type layer 24. P-type microcrystalline layer 21 was formed by introducing silane, diborane and hydrogen into the chamber under a pressure of 350 Pa, and by applying high-frequency power at an intensity of 150 mW/cm² for exciting plasma, and then the film thickness was set to 15 nm. Successively, amorphous silicon carbide layer 22 was formed by introducing silane, diborane, hydrogen, and methane into the chamber under a pressure of 133 Pa, and by applying high-frequency power at an intensity of 170 mW/cm² for exciting plasma. Here, the film thickness was set to 10 nm. Then, i-type amorphous silicon layer 23 was formed to 300 nm thickness by introducing silane and hydrogen as the film-forming gas into the chamber under a pressure of 50 Pa, and by applying high-frequency power at an intensity of 120 mW/cm² for exciting plasma. Further, n-type layer 24 was formed to 10 nm thickness by introducing silane, phosphine and hydrogen as the film-forming gas into the chamber under a pressure of approximately 350 Pa, and by applying high-frequency power at an intensity of 170 mW/cm² for exciting plasma. Thereafter, the substrate having amorphous silicon photoelectric conversion unit 20 thus formed was placed in a chamber for forming back electrode layer 30. Back electrode layer 30 is constituted of zinc oxide layer 31 and Ag layer 32, and zinc oxide layer 31 was formed by a CVD method. Hydrogen and diborane were introduced at 1500 sccm and 500 sccm respectively, and the deposition temperature was held at 150° C. for 30 minutes. The zinc oxide film was deposited to 60 nm thickness under conditions in which vaporized water and diethyl zinc were introduced at 900 sccm and 800 sccm respectively and the pressure in the film-forming chamber was held at 45 Pa. Ag layer 32 of 200 nm thickness was formed on zinc oxide layer 31 by a sputtering method, and the thin film photoelectric conversion device was thus fabricated.

The thin film photoelectric conversion device thus obtained was irradiated with AM 1.5 light at energy density of 100 mW/cm² and its output properties were measured. It was found that the open-circuit voltage (Voc) was 0.899V, the short-circuit current density (Jsc) was 16.0 mA/cm², the fill factor (F.F.) was 72.7%, and the conversion efficiency (Eff.) was 10.5%.

### Comparative Example 1

A thin film photoelectric conversion device in Comparative Example 1 was fabricated in a similar manner as in Example 1, except that the zinc oxide film was not etched. The thin film photoelectric conversion device fabricated in Comparative Example 1 was irradiated with AM 1.5 spectrum at energy density of 100 mW/cm² and its output properties were measured at a temperature of 25° C. It was found that Voc was 0.889V, Jsc was 16.1 mA/cm², F.F. was 71.1%, and Eff. was 10.2%.

### Examples 2 to 5

Zinc oxide layer 13 deposited on transparent insulator base 10 by the same method as in Example 1 was treated with 1 vol % acetic acid aqueous solution. Here, the time for treatment, which was set to 5 seconds in Example 1, was varied in a range from 10 to 40 seconds. Specifically, the time for treatment with 1 vol % acetic acid aqueous solution was set to 10 seconds in Example 2, 20 seconds in Example 3, 30 seconds in Example 4, and 40 seconds in Example 5. The thin film photoelectric conversion device fabricated on the substrate in each embodiment as above was irradiated with AM 1.5 spectrum at energy density of 100 mW/cm² and its output properties were measured at a temperature of 25° C. The results are shown in Tables 1, 2 and 3, together with results in Example 1 and Comparative Example 1. Here, Table 1 shows the relation between the time for treatment and variation in the SDR, Table 2 shows the relation between the time for treatment and variation in the haze ratio, and Table 3 shows the relation between the time for treatment and the output properties. As can be seen from these results, when the time for treatment is short, Voc is improved by the effect of only removal of steep protrusions in the textured structure, but when the time for treatment is extended, the texture is also promoted by etching itself and thus the problem of sharper level variation arises similarly as in the prior art and then Voc or F.F. decreases. Therefore, the etching should be performed such that the variation in the haze ratio and the SDR is in the prescribed ranges in Table 1 and 2.

TABLE 1

| | Time for | | | |
|---|---|---|---|---|
| | Treatment | SDR (before | SDR (after | Rate of |
| | (sec) | treatment) | treatment) | Change (%) |
| Example 1 | 5 | 67 | 60 | −10 |
| Example 2 | 10 | 66 | 55 | −17 |
| Example 3 | 20 | 81 | 59 | −26 |
| Example 4 | 30 | 73 | 43 | −30 |
| Example 5 | 40 | 91 | 44 | −47 |

TABLE 2

| | | Haze Ratio | Haze Ratio | |
|---|---|---|---|---|
| | Time for | (before | (after | |
| | Treatment | treatment) | treatment) | Rate of |
| | (sec) | (%) | (%) | Change (%) |
| Example 1 | 5 | 18 | 19 | 1 |
| Example 2 | 10 | 26 | 24 | −6 |
| Example 3 | 20 | 21 | 26 | 20 |
| Example 4 | 30 | 24 | 30 | 23 |
| Example 5 | 40 | 25 | 33 | 31 |

TABLE 3

| | Time for | | | | |
|---|---|---|---|---|---|
| | Treatment | Voc | Jsc | FF | Eff. |
| | (sec) | (V) | (mA/cm²) | (%) | (%) |
| Comparative | None | 0.889 | 16.1 | 71.1 | 10.2 |
| Example 1 | | | | | |
| Example 1 | 5 | 0.899 | 16 | 72.7 | 10.5 |
| Example 2 | 10 | 0.900 | 16.1 | 72.2 | 10.4 |
| Example 3 | 20 | 0.895 | 16 | 71.5 | 10.2 |
| Example 4 | 30 | 0.892 | 15.8 | 71 | 10.0 |
| Example 5 | 45 | 0.889 | 15.9 | 69.2 | 9.8 |

1. A method of producing a substrate for a thin film photoelectric conversion device, wherein a transparent conductive film formed on a transparent insulator base, which is mainly composed of zinc oxide and having a haze ratio of at least 5%, is etched with an acid or alkali solution.

2. The method of producing a substrate for a thin film photoelectric conversion device according to claim 1, wherein said transparent conductive film is formed with a CVD method.

3. The method of producing a substrate for a thin film photoelectric conversion device according to claim 1, wherein said transparent conductive film has a haze ratio in a range from 10% to 40% before said etching.

4. The method of producing a substrate for a thin film photoelectric conversion device according to claim 1, wherein said etching causes a change rate of at most ±20% in the haze ratio and a decrease rate of 10% to 26% in SDR (surface area ratio).

5. The method of producing a substrate for a thin film photoelectric conversion device according to claim 1, wherein said etching is performed by immersing said transparent conductive film on said transparent insulator base into 0.05 to 2 vol % acetic acid solution for 1 to 20 seconds.

6. The method of producing a substrate for a thin film photoelectric conversion device according to claim 1, wherein said acid solution is a liquid composed of one or more selected from the group consisting of acetic acid, hydrochloric acid, nitric acid, and hydro-fluoric acid.

7. The method of producing a substrate for a thin film photoelectric conversion device according to claim 1, wherein said alkali solution is a liquid composed of one or more selected from the group consisting of sodium hydroxide, ammonia, potassium hydroxide, and calcium hydroxide.

8. A thin film photoelectric conversion device comprising a photoelectric conversion unit and a back electrode layer stacked in this order on the substrate formed by the method of claim 1.
